(19) United States
(12) Patent Application Publication
(10) Pub. No.: US 2003/0151428 A1
(43) Pub. Date: Aug. 14, 2003

(54) 5 Volt tolerant input/output buffer

(76) Inventor: Paul H. OuYang, San Jose, CA (US)

Correspondence Address: Paul H. OuYang, DMEL, Inc., Suite 203, 3150 De La Cruz Blvd., Santa Clara, CA, 95054, US

(21) Appl. No.: 10/364,265

(22) Filed: Feb. 11, 2003

Related U.S. Application Data
(60) Provisional application No. 60/356,527, filed on Feb. 12, 2002.

(51) Int. Cl. H03K 19/02

(52) U.S. Cl. 326/56

(57) ABSTRACT

A circuit and a method are disclosed to provide a tristate input/output buffer which is compatible with 5 volt input signals, applied to its input/output (I/O) node, while operating with a 3 volt power supply and is resistant to CMOS latchup. The 5 volt compatibility is achieved by inserting an additional p-channel transistor in series with the existing p-channel transistor and circuitry to control the additional p-channel transistor. The control circuit is comprised of 2 transistors. The CMOS latchup resistance is provided by a N-well bias generator that changes the N-well bias to be equal to the higher of the 2 voltages, VDD or the voltage present at the I/O pad. The N-well bias generator is comprised of 3 transistors.

### BACKGROUND OF INVENTION

1. Field of Invention

The invention relates to a CMOS integrated circuit, more particularly to a tristate input/output buffer which is compatible with a higher input voltage than the power supply voltage of the integrated circuit.

2. Description of Prior Art

In the operation of integrated circuits, an integrated circuit that is fabricated to operate from a given voltage is often required to interface to an integrated circuit that is fabricated to operate from a higher voltage. For example an integrated circuit fabricated to operate from 2.5 volts may be required to interface to integrated circuits that operate from 3.3 volts and/or integrated circuits that operate from 5 volts. The signals that are supplied from the integrated circuits that operate from the higher voltages will be of higher voltages. The integrated circuits that are fabricated to operate from lower voltages may contain tristate input/output buffers that contain circuitry that protects the integrated circuit from conducting excessive current under the condition and/or forward biasing the parasitic bipolar transistors contained in the output buffer portion of the tristate input/output buffer. The tristate input/output buffers require complex circuitry and/or require complex fabrication processes that are undesirable. Also, the input/output buffers do not contain the degree of protection against forward biasing of the parasitic bipolar transistors as is required in many uses.

A circuit of such a tristate input/output buffer is shown in FIG. 1 and will be explained next. FIG. 1 shows only the output buffer and N-Well Bias generator portion of the circuit. The input buffer portion in the tristate input/output buffer is not shown. In the case when OE (Output Enable) is logical low, regardless of the relationship of the voltage at the I/O (Input/Output) pad 113 and VDD, p-channel transistor 100 does not conduct, isolating the I/O pad 113 from VDD and n-channel transistors 101 and 102 do not conduct isolating the I/O pad 113 from ground. This is the disabled state of the output buffer portion.

Still referring to FIG. 1, when OE is at a logical HIGH, a copy of the input signal IN will be presented at the I/O pad 113.

Still referring to FIG. 1, the p-channel transistors 114 and 115 make up a conventional substrate bias control circuit, which provides the N-Well bias. When OE is at a logical HIGH or LOW, and the voltage at the I/O pad 113 is equal to VDD, neither p-channel transistors 114 nor 115 conduct. This results in a failure to drive the N-Well Bias node to either VDD or the voltage present at the I/O pad 113. In this condition, the voltage present at the N-Well bias node is unknown and may be at a lower voltage than VDD and the voltage present at the I/O pad 113.

Referring to FIG. 2, it will be explained that the parasitic bipolar transistors in the p-channel transistor 100 may forward bias resulting in excessive current flow from VDD to ground, which is the same as the p-substrate, and/or from the I/O pad 113 to ground. The parasitic bipolar transistors are represented as a diode 123 and 125 connected from the emitter to the base of a PNP transistor 122 and 124 respectively. When the N-Well Bias node is not actively driven, as is the case when VDD is equal to the voltage at the I/O pad 113, it will go to a voltage 1 VD lower than VDD. In this state the PNP transistors 122 and 124 are near conducting but not yet conducting. In the case when VDD rises to a higher voltage quickly, the emitter of transistor 122 rises at the same time, but there is a time delay before the base of transistor 122 rises causing transistor 122 to conduct excessive current to ground. In the case when VDD is equal to the voltage at the I/O pad 113 and then the voltage at the I/O pad 113 rises quickly, there will be a delay before the base of transistor 124 rises causing transistor 124 will forward bias causing excessive current to flow from the I/O pad to ground.

It is desirable to provide a circuit and a method for an input/output buffer to operate with a voltage present on its input/output node which is higher than its power supply voltage while not loading the input signal present on the input/output node. In addition, it is also desirable to provide an input/output buffer that does not require complex manufacturing requirements, e.g., the N-well. Further, it is desireable to provide an input/output buffer that is not susceptible to forward biasing of the parasitic bipolar transistors and CMOS Latch-up.

### SUMMARY

In accordance with an embodiment of the present invention, an additional p-channel transistor is inserted in series with the circuit power supply (VDD), a p-channel transistor, and the input/output node. A circuit comprised of two transistors control the additional p-channel transistor. Moreover, a N-well bias voltage generating circuit that provides the higher of the voltages, VDD or the voltage at the input/output node, to the n-well of all the p-channel transistors prevent forward biasing the parasitic diodes contained in the p-channel transistors.

### BRIEF DESCRIPTION OF THE DRAWINGS

FIG. 1 is a circuit diagram of the related art.

FIG. 2 is a circuit diagram of a portion of FIG. 1 showing the parasitic diodes in the p-channel and n-channel transistors.

FIG. 3 is a high level block diagram of the present invention.

FIG. 4 is a circuit diagram of the preferred embodiment of the present invention.

FIG. 5 is a truth table for the operation of the preferred embodiment.

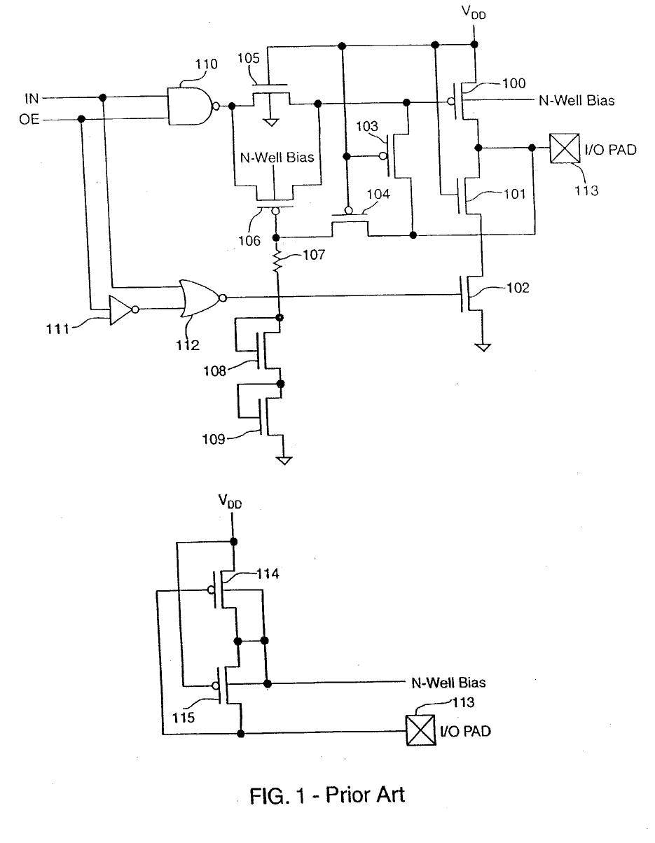

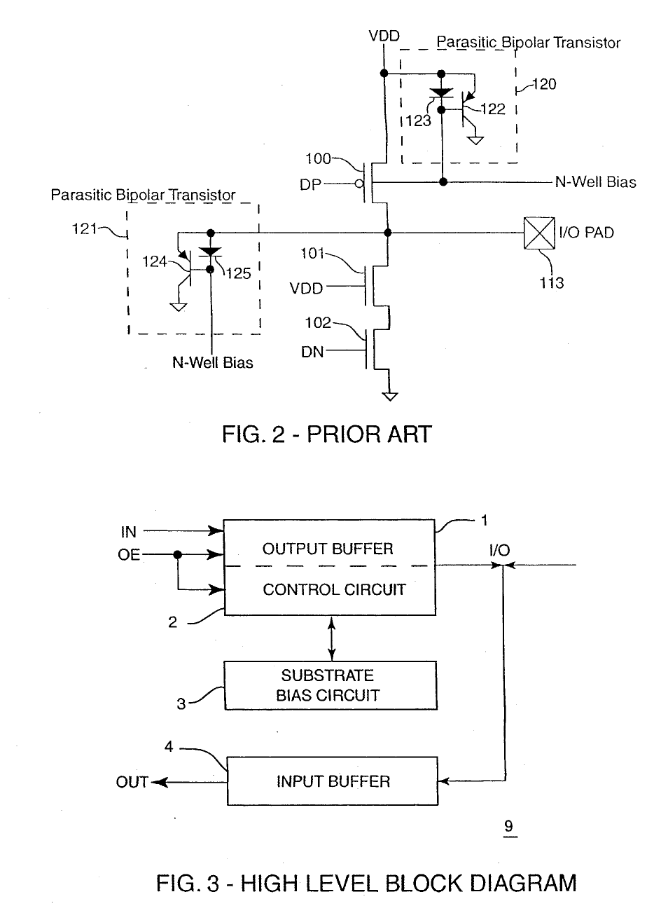

### DETAILED DESCRIPTION

A high level block diagram of the present invention is shown in FIG. 3 and depicts a tristate input/output (I/O) buffer 9 that includes an output buffer 1, a control circuit 2, a N-well bias circuit 3, and an input buffer 4. The output buffer 1 has an enabling/disabling input OE (Output Enable), a data input IN, and a tristate output connected to the I/O node. The tristate output provides a copy of IN on the I/O node when OE is high (the enabled state) and presents a high impedance when OE is low (the disabled state). In the disabled state an input signal may be applied to the I/O node. The input buffer 4 will present a copy of the input signal at the OUT node. Control circuit 2 prevents loading of the input signal by the output buffer 1 when the output buffer 1 is in the high impedance mode (disabled). The N-well bias circuit 3 provides a voltage to all the p-channel transistors equal to the highest voltage in the circuit, whether that voltage is VDD or from an external source applied to the I/O node to avoid forward biasing the parasitic diode in those p-channel transistors and to avoid CMOS latch up.

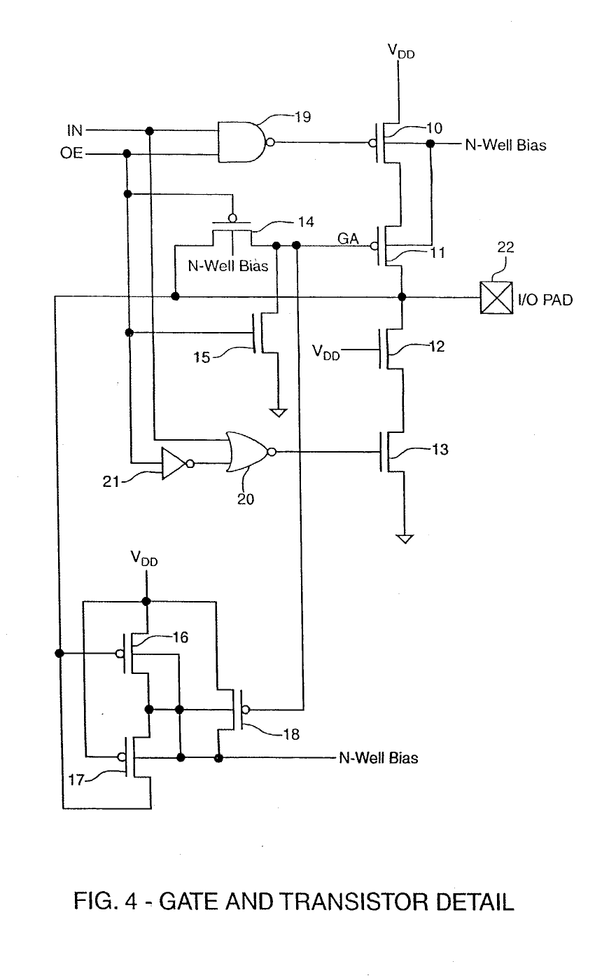

A circuit diagram of one embodiment of the present invention is shown in FIG. 4 and depicts the transistor and gate details of the output buffer 1, control circuit 2, and N-well bias circuit 3 of FIG. 3. Details of the input buffer 4 are not shown so as to avoid unnecessarily obfuscating the present invention. Input buffer 4, however, is well known in the art and thus need not be explained in detail.

Relating the circuit diagram FIG. 4 to the high level block diagram FIG. 3, the Output Buffer 1 is includes NAND gate 19, NOR Gate 20, inverter 21, p-channel transistors 10 and 11, and n-channel transistors 12 and 13. The Control Circuit 2 includes p-channel transistor 14 and n-channel transistor 15. The N-well bias circuit 3 includes p-channel transistors 16, 17, and 18. I/O PAD 22 is the connection to voltage signals from outside the integrated circuit.

Referring to FIG. 4, the data input IN is connected to the NAND gate 19 input and to NOR gate 20 input. The output enable input OE is connected to the other input of the NAND gate 19, and to the inverter 21 input. The output of the inverter 21 is connected to the other input of NOR gate 20. The output of NAND gate 19 is connected to the gate of transistor 10. The output of NOR gate 20 is connected to the gate of transistor 13. The power supply VDD is connected to the drain of transistor 10. The source of transistor 10 is connected to the drain of transistor 11. The gate of transistor 11 is connected to the source of transistor 14, the drain of transistor 15 and the gate of transistor 18. The source of transistor 11 is connected to the I/O pad 22, the drain of transistor 12, the drain of transistor 14, the gate of transistor 16, and the source of transistor 17. The gate of transistor 12 is connected to VDD. The source of transistor 12 is connected to the drain of transistor 13. The source of transistor 13 is connected to ground. This describes the output buffer portion of the circuit and its connections to the control circuit portion and the bias generator circuit portion.

Still referring to FIG. 4, the output enable OE is also connected to the gate of transistor 14 and the gate of transistor 15. The source of transistor 15 is connected to ground. This describes the control circuit portion.

Still referring to FIG. 4, VDD is connected to the drain of transistor 16, the gate of transistor 17, and the drain of transistor 18. The source of transistor 16 is connected to the drain of transistor 17, the body of transistors 16, 17, 18, 14, 10, 11, and the source of transistor 18. This describes the N-well bias circuit portion and its connections to the output buffer portion and the control circuit portion.

Still referring to FIG. 4, the function of the output buffer portion of the circuit is now explained. There are 4 states that the output buffer can have as defined by the states of the inputs IN and OE. The first state described is when both IN and OE are logical LOW. Both inputs to NAND gate 19 will be LOW resulting in the output of NAND gate 19 and the gate of transistor 10 being logical HIGH. Transistor 10 will not conduct, isolating its source from VDD. Likewise transistor 11 is isolated from VDD and I/O pad 22 is isolated from VDD, blocking any current that may otherwise flow between the VDD node and the I/O pad 22. The input of inverter 21 is LOW resulting in its output and the input of NOR gate 20 being HIGH. The other input of NOR gate 20 is LOW resulting in its output and the gate of transistor 13 being LOW. Transistor 13 will not conduct, isolating the drain of transistor 13 and source of transistor 12 from ground. Since the source of n-channel transistor 12 is isolated from ground, its drain and I/O pad 22 are also isolated from ground. This results in the output driver presenting a high impedance to the I/O pad 22.

Still referring to FIG. 4, the second state is defined as IN being a logical HIGH and OE being a logical LOW. The output states of the NAND gate 19 and NOR gate 20 are the same as in the description above of the first state. This results in the output driver presenting a high impedance to the I/O pad 22, the same as in the first state.

Still referring to FIG. 4, the third state is defined as IN being a logical LOW and OE being a logical HIGH. One input of NAND gate 19 is LOW while the other input is HIGH resulting in its output and the gate of transistor 10 being HIGH. As a result, transistor 10 does not conduct isolating its source and the drain of transistor 11 from VDD. Likewise, the I/O pad 22 is isolated from VDD. The input of inverter 21 is HIGH resulting in its output and one of the inputs of NOR gate 20 being LOW. The other input of NOR gate 20 is also LOW resulting in its output and the gate of transistor 13 being HIGH. Transistor 13 conducts, bringing its drain and the source of transistor 12 to ground. Transistor 12 conducts since its gate is connected to VDD, bringing its drain and I/O pad 22 to ground. Therefore a copy of the input IN is presented at the I/O pad 22.

Still referring to FIG. 4, the forth state is defined as both IN and OE being a logical HIGH. Both inputs to NAND gate 19 are therefore HIGH resulting in its output and the gate of transistor 10 being LOW. Therefore transistor 10 conducts, bring its source and the drain of transistor 11 to VDD. Likewise, transistor 11 conducts as will be described later, and its source and I/O pad 22 are brought to VDD presenting a copy of the input IN at the I/O pad 22. The input of the inverter 21 is HIGH resulting in its output and one of the inputs to NOR gate 20 being LOW. The other input of NOR gate 20 is HIGH resulting in its output and the gate of transistor 13 being LOW. Therefore transistor 13 does not conduct, isolating its drain and the source of transistor 12 from ground. Transistor 12 conducts, but since its source is isolated from ground, its drain and I/O pad 22 are also isolated from ground.

Still referring to FIG. 4, the operation of the control circuit portion is described. The function of the control circuit is to isolate the I/O pad 22 from VDD if the voltage present at I/O pad 22 is greater than VDD. The control circuit portion must not interfere with the normal operation of the output buffer at all other times. The first state is defined as OE HIGH, in which case the gate of transistor 15 is high allowing it to conduct and bring the gate of transistor 11 LOW, allowing it to conduct and enabled the operation of the output buffer to drive to VDD when input IN is HIGH as previously described. The second state is defined as OE LOW and the voltage present at the I/O pad 22 higher than VDD. In this state the gate of transistor 15 is LOW isolating its drain and the gate of transistor 11 from ground. The gate of transistor 14 is LOW allowing it to conduct. The source of transistor 14 and the gate of transistor 11 will therefore rise up to the voltage present at the I/O pad 22. Transistor 11 will not conduct isolating the I/O pad from the source of transistor 10 and VDD. This action of isolating the I/O pad 22 from VDD allows the present invention to tolerate voltages of up to 2 volts greater than VDD to be present at the I/O pad 22.

Still referring to FIG. 4, the function of the N-well bias circuit will be described. The function of the N-well bias circuit is to drive the voltage present on the body of all p-channel transistors in the present invention to the highest voltage present in the circuit, whether that voltage is from VDD of from an external source presented at the I/O pad 22. By presenting the highest voltage that is present in the circuit, forward biasing of the parasitic diodes present in the p-channel transistors will be avoided resulting in a high resistance to CMOS latchup. In the case when VDD is equal to or higher than the voltage present at the I/O pad 22 and OE is at a logical LOW, transistor 16 will conduct allowing VDD to pass to the N-WELL BIAS node. Transistor 17 will not conduct since VDD is connected to its gate and the voltage from the I/O pad 22 is lower than VDD and connected to its source, isolating the N-WELL BIAS node from the voltage present at I/O pad 22. Since OE is LOW and transistor 14 conducting, the voltage present at the I/O pad will also be present at the gate of transistor 18, causing transistor 18 to conduct VDD to the N-WELL BIAS node as well. This is a redundant path for VDD to reach the N-WELL BIAS node in this case.

Still referring to FIG. 4, the function of the N-well bias circuit will be described when the voltage present at I/O pad 22 is higher than VDD and OE is at a logical LOW. Transistor 16 will not conduct since its gate is higher than its drain, isolating the N-WELL BIAS node from VDD. Transistor 17 will conduct since its gate is lower than its source connecting N-WELL BIAS node to the voltage present at the I/O pad 22.

Still referring to FIG. 4, the function of the N-well bias circuit is described when OE is at a logical HIGH. In this case the voltage present at the I/O pad 22 will be provided by the output driver circuit and will not be higher than VDD nor lower than ground. The gate of transistor 15 will be HIGH allowing it to conduct and bringing its drain and the gate of transistor 18 to ground. Transistor 18 will conduct bringing N-WELL BIAS node to the level of VDD. A possible redundant path from VDD to the N-WELL BIAS node exists through transistor 16 when the voltage at I/O pad 22 is lower than VDD, although when the voltage at the I/O pad 22 is the same as VDD, the path through transistor 16 will not conduct making the path through transistor 18 the primary path.

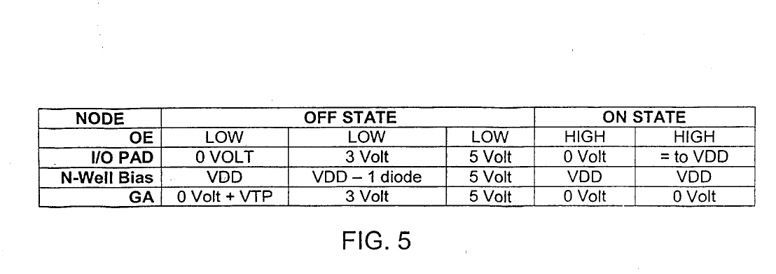

Referring to FIG. 5 and FIG. 4, and as described above, when OE is at a logical LOW, the output buffer is in the OFF STATE. When OE is at a logical LOW and the I/O Pad 22 is at 0 volts, the N-Well Bias is equal to VDD and node GA is equal to the I/O Pad 22 plus 1 VTP. When OE is LOW and the voltage at the output buffer is at 3 volts, the N-Well Bias is equal to VDD minus one diode voltage and node GA is equal to 3 volts. When OE is at a low and the voltage at the I/O pad is equal to 5 volts, the N-Well Bias is equal to 5 volts and node GA is equal to 5 volts.

Still referring to FIG. 5 and FIG. 4, and as described above, when OE is at a logical HIGH, the output buffer is in the enabled or ON STATE. When OE is HIGH and the voltage at the I/O pad is in the range of 0 volts to VDD, the N-Well Bias is equal to VDD and node GA is equal to 0 volts.

This invention describes a non-inverting buffer. It is applicable to an inverting buffer also, which can be obtained by simply replacing NAND gate 19 and NOR gate 20 with AND and OR gates respectively.

While the invention has been particularly shown and described with reference to the preferred embodiments thereof, it will be understood by those skilled in the art that various changes in form and details may be made without departing from the spirit and scope of the invention.

What is claimed is:

1. A tristate buffer comprising:
a power supply providing a supply voltage;
an input buffer coupled to receive the supply voltage;
an output buffer coupled to receive the supply voltage and to an input-output node;
a control circuit coupled with the input buffer and the output buffer, the control circuit being coupled to receive the supply voltage; and
a bias circuit coupled with the input buffer, the output buffer, and the control circuit,
wherein an output voltage at the input-output node comprises a voltage approximately equal to either the supply voltage or an external voltage.

2. The tristate buffer of claim 1 wherein the output buffer comprises a first transistor having a drain coupled to receive the supply voltage, a second transistor having a drain coupled to the input-output node and a gate coupled to the supply voltage a third transistor having a drain coupled to the source of the first transistor and a source coupled to the drain of the second transistor, and a fourth transistor having a drain coupled to the source of the second transistor and a source connected to a ground potential.

3. The tristate buffer of claim 2 wherein the control circuit is coupled to a gate of each of the first transistor, third transistor, and fourth transistor.

4. The tristate buffer of claim 3 wherein the control circuit comprises a NAND gate connected to the gate of the first transistor and a NOR gate coupled to the gate of the fourth transistor.

5. The tristate buffer of claim 2 wherein the control circuit comprises a fourth transistor having the gate coupled to receive an enable signal and drain coupled to the gate of the third transistor.

6. The tristate buffer of claim 2 wherein the control circuit comprises an AND gate connected to the gate of the first transistor and an OR gate coupled to the gate of the second transistor.

7. The tristate buffer of claim 1 wherein the output buffer comprises means for isolating the supply voltage from the input-output node.

8. The tristate buffer of claim 1 wherein the input-output node comprises a pad.

9. A tristate buffer comprising:
a power supply providing a supply voltage;
an input buffer coupled to receive the supply voltage;
an output buffer coupled to receive the supply voltage, the output buffer comprising a first transistor and a second transistor coupled between the supply voltage and an input-ouput node;
a control circuit coupled with the input buffer and the output buffer, the control circuit being coupled to receive the supply voltage; and
a bias circuit the input buffer and the output buffer, and the control circuit.

10. The tristate buffer of claim 9 wherein the control circuit is coupled to a gate of each of the first transistor and the second transistor to simultaneously enable conduction by both the first transistor and the second transistor.

11. The tristate buffer of claim 9 wherein the control circuit comprises a NAND gate connected to the gate of the first transistor.

12. The tristate buffer of claim 11 wherein the control circuit further comprises a third transistor having the gate coupled to receive an enable signal, a drain coupled to the gate of the second transistor, and a source coupled to the input-output node, and a fourth transistor comprising a gate coupled to receive the enable signal, and a drain coupled to the drain of the third transistor.

13. The tristate buffer of claim 9 wherein the control circuit comprises an AND gate connected to the gate of the first transistor.

14. The tristate buffer of claim 9 wherein the input-output node comprises a pad.

15. The tristate buffer of claim 9 wherein the output buffer comprises means for reducing current flow between the supply voltage and the input-output node.

16. An output buffer of tristate buffer comprising:
a first transistor having a drain coupled to a supply voltage, a gate coupled to a control circuit, and a source;
a second transistor having a drain coupled to the source of the first transistor, a gate coupled to the control circuit, and a source coupled to an input-output node of the tristate buffer; and
a third transistor having a drain coupled to the source of the second transistor, a gate coupled to the control circuit and a source.

17. The output buffer of claim 16 wherein the drain of the second transistor is connected to the source of the first transistor.

18. The output buffer of claim 16 wherein the gate of the first transistor and the gate of the second transistor are connected to the control circuit.

19. The output buffer of claim 16 wherein the control circuit provides a signal to the gate of each of the first transistor and the second transistor at a substantially similar time.

20. The output buffer of claim 16 further comprising a fourth transistor having a drain coupled to the source of the second transistor, a source coupled to the drain of the third transistor and a gate coupled to the supply voltage.
